(19) United States
(12) Patent Application Publication
(10) Pub. No.: US 2020/0209757 A1
(43) Pub. Date: Jul. 2, 2020

(54) Lithographic Apparatus, Lithographic Projection Apparatus and Device Manufacturing Method

(71) Applicants: ASML Netherlands B.V., Veldhoven (NL); Carl Zeiss SMT GmbH, Oberkochen (DE)

(72) Inventors: Hans BUTLER, Best (NL); Bernhard Mathias GEUPPERT, Aalen (DE); Erik Roelof LOOPSTRA, Eindhoven (NL); Maurice Willem Jozef Etiënn WIJCKMANS, Eindhoven (NL)

(73) Assignees: ASML Netherlands B.V., Veldhoven (NL); Carl Zeiss SMT GmbH, Oberkochen (DE)

(21) Appl. No.: 16/319,587

(22) PCT Filed: Jun. 16, 2017
(86) PCT No.: PCT/EP2017/064738

§ 371 Date: Jan. 22, 2019

(30) Foreign Application Priority Data
Jul. 22, 2016 (EP) 16180675.7

(51) Int. Cl. G03F 7/20

(52) U.S. Cl. CPC G03F 7/709; G03F 7/70233; G03F 7/70266; G03F 7/70358; G03F 7/70833; G03F 7/70725; G03F 7/70758; G03F 7/70775

(57) ABSTRACT

The present invention relates to a lithographic apparatus, comprising: —a base frame (10), adapted for mounting the lithographic apparatus (1) on a support surface (9), —a projection system (20) comprising: —a force frame (30), —an optical element (21) which is moveable relative to the force frame, —a sensor frame (40), which is separate from the force frame, —at least one sensor which is adapted to monitor the optical element, comprising at least one sensor (25) element which is mounted to the sensor frame, —a force frame support (31), which is adapted to support the force frame on the base frame, —an intermediate frame (45), which is separate from the force frame, —a sensor frame coupler (41), which is adapted to couple the sensor frame to the intermediate frame, —an intermediate frame support (46), which is separate from the force fame support and adapted to support the intermediate frame on the base frame.

### CROSS-REFERENCE TO RELATED APPLICATIONS

This application claims priority of EP application 16180675.7 which was filed on 22 Jul. 2016 and which is incorporated herein in its entirety by reference.

### BACKGROUND

### Field of the Invention

The present invention relates to a lithographic apparatus, a lithographic projection apparatus and a method for manufacturing a device in which use is made of a lithographic apparatus.

### Description of the Related Art

A lithographic apparatus is a machine that applies a desired pattern onto a substrate, usually onto a target portion of the substrate. A lithographic apparatus can be used, for example, in the manufacture of integrated circuits (ICs). In such a case, a patterning device, which is alternatively referred to as a mask or a reticle, may be used to generate a circuit pattern to be formed on an individual layer of the IC. This pattern can be transferred onto a target portion (e.g. including part of, one, or several dies) on a substrate (e.g. a silicon wafer). Transfer of the pattern is typically via imaging onto a layer of radiation-sensitive material (resist) provided on the substrate. In general, a single substrate will contain a network of adjacent target portions that are successively patterned. Conventional lithographic apparatus include so-called steppers, in which each target portion is irradiated by exposing an entire pattern onto the target portion at once, and so-called scanners, in which each target portion is irradiated by scanning the pattern through a radiation beam in a given direction (the “scanning”-direction) while synchronously scanning the substrate parallel or anti parallel to this direction. It is also possible to transfer the pattern from the patterning device to the substrate by imprinting the pattern onto the substrate.

A lithographic apparatus often comprises a projection system which comprises at least one optical element such as a mirror or a lens. An illumination system conditions a beam of radiation which is sent to a patterning device. From the patterning device, the beam enters the projection system, which transfers the radiation beam to a substrate.

The optical element needs to be accurately positioned relative to at least the radiation beam in order to achieve the desired projection accuracy, and therewith to reduce overlay error in the image on the substrate.

Optionally, the projection system comprises multiple optical elements. In that case, the position of the optical elements relative to each other needs to be accurately controlled in order to obtain the desired projection accuracy. This position control becomes more complicated when it is desired that one or more of the optical elements perform a scanning motion, for example in order to compensate for thermal expansion of the substrate.

### SUMMARY

It is desirable to provide a lithographic apparatus and a lithographic projection apparatus which allows to obtain a good projection accuracy.

According to an embodiment of the invention, a lithographic apparatus is provided which comprises:
a base frame, which is adapted for mounting the lithographic apparatus on a support surface,
a projection system, which comprises:
a force frame,
an optical element which is moveable relative to the force frame,
a sensor frame, which is separate from the force frame,
at least one sensor which is adapted to monitor the optical element, which sensor comprises at least one sensor element which is mounted to the sensor frame,
a force frame support, which is adapted to support the force frame on the base frame,
an intermediate frame, which is separate from the force frame,
a sensor frame coupler, which is adapted to couple the sensor frame to the intermediate frame,
an intermediate frame support, which is separate from the force fame support and which is adapted to support the intermediate frame on the base frame.

In another embodiment of the invention, a lithographic apparatus is provided which comprises:
an illumination system configured to condition a radiation beam;
a support constructed to support a patterning device, the patterning device being capable of imparting the radiation beam with a pattern in its cross-section to form a patterned radiation beam;
a base frame, which is adapted for mounting the lithographic apparatus on a support surface;
a substrate table constructed to hold a substrate; and
a projection system configured to project the patterned radiation beam onto a target portion of the substrate, which projection system comprises:
a force frame,
an optical element which is moveable relative to the force frame,
a sensor frame, which is separate from the force frame,
at least one sensor which is adapted to monitor the optical element, which sensor is mounted to the sensor frame,
a force frame support, which is adapted to connect the force frame and the base frame to each other,
an intermediate frame, which is separate from the force frame,
a sensor frame coupler, which is adapted to connect the sensor frame and the intermediate frame to each other,
an intermediate frame support, which is separate from the force fame support and which is adapted to connect the intermediate frame and the base frame to each other.

In another embodiment of the invention, a lithographic projection apparatus is provided which is arranged to project a pattern from a patterning device onto a substrate, which lithographic projection apparatus comprises:
a base frame, which is adapted for mounting the lithographic apparatus on a support surface,
a projection system, which comprises:
a force frame,
an optical element which is moveable relative to the force frame,
a sensor frame, which is separate from the force frame,
at least one sensor which is adapted to monitor the optical element, which sensor is mounted to the sensor frame,
a force frame support, which is adapted to connect the force frame and the base frame to each other,
an intermediate frame, which is separate from the force frame,
a sensor frame coupler, which is adapted to connect the sensor frame and the intermediate frame to each other,
an intermediate frame support, which is separate from the force fame support and which is adapted to connect the intermediate frame and the base frame to each other.

In another embodiment of the invention, a device manufacturing method is provided comprising transferring a pattern from a patterning device onto a substrate, wherein use is made of a lithographic apparatus according to the invention.

In another embodiment of the invention, a device manufacturing method is provided comprising projecting a patterned beam of radiation onto a substrate, wherein use is made of a lithographic apparatus according to the invention.

### BRIEF DESCRIPTION OF THE DRAWINGS

Embodiments of the invention will now be described, by way of example only, with reference to the accompanying schematic drawings in which corresponding reference symbols indicate corresponding parts, and in which:

FIG. 1 depicts a lithographic apparatus according to an embodiment of the invention;

FIG. 2 schematically shows a first embodiment of a lithographic apparatus according to the invention,

FIG. 3 schematically shows a second embodiment of the lithographic apparatus according to the invention,

FIG. 4 schematically shows a third embodiment of the lithographic apparatus according to the invention,

FIG. 5 schematically shows a fourth embodiment of the lithographic apparatus according to the invention,

FIG. 6 schematically shows a fifth embodiment of the lithographic apparatus according to the invention.

### DETAILED DESCRIPTION

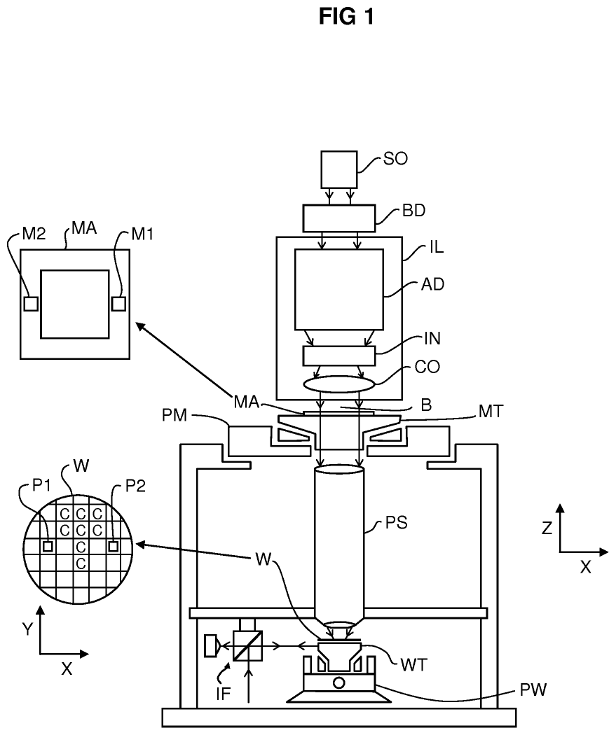

FIG. 1 schematically depicts a lithographic apparatus according to one embodiment of the invention. The apparatus includes an illumination system (illuminator) IL configured to condition a radiation beam B (e.g. UV radiation or any other suitable radiation), a mask support structure (e.g. a mask table) MT constructed to support a patterning device (e.g. a mask) MA and connected to a first positioning device PM configured to accurately position the patterning device in accordance with certain parameters. The apparatus also includes a substrate table (e.g. a wafer table) WT or “substrate support” constructed to hold a substrate (e.g. a resist coated wafer) W and connected to a second positioning device PW configured to accurately position the substrate in accordance with certain parameters. The apparatus further includes a projection system (e.g. a refractive projection lens system) PS configured to project a pattern imparted to the radiation beam B by patterning device MA onto a target portion C (e.g. including one or more dies) of the substrate W.

The illumination system may include various types of optical components, such as refractive, reflective, magnetic, electromagnetic, electrostatic or other types of optical components, or any combination thereof, for directing, shaping, or controlling radiation.

The mask support structure supports, i.e. bears the weight of, the patterning device. It holds the patterning device in a manner that depends on the orientation of the patterning device, the design of the lithographic apparatus, and other conditions, such as for example whether or not the patterning device is held in a vacuum environment. The mask support structure can use mechanical, vacuum, electrostatic or other clamping techniques to hold the patterning device. The mask support structure may be a frame or a table, for example, which may be fixed or movable as required. The mask support structure may ensure that the patterning device is at a desired position, for example with respect to the projection system. Any use of the terms “reticle” or “mask” herein may be considered synonymous with the more general term “patterning device.”

The term “patterning device” used herein should be broadly interpreted as referring to any device that can be used to impart a radiation beam with a pattern in its cross-section so as to create a pattern in a target portion of the substrate. It should be noted that the pattern imparted to the radiation beam may not exactly correspond to the desired pattern in the target portion of the substrate, for example if the pattern includes phase-shifting features or so called assist features. Generally, the pattern imparted to the radiation beam will correspond to a particular functional layer in a device being created in the target portion, such as an integrated circuit.

The patterning device may be transmissive or reflective. Examples of patterning devices include masks, programmable mirror arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted so as to reflect an incoming radiation beam in different directions. The tilted mirrors impart a pattern in a radiation beam which is reflected by the minor matrix.

The term “projection system” used herein should be broadly interpreted as encompassing any type of projection system, including refractive, reflective, catadioptric, magnetic, electromagnetic and electrostatic optical systems, or any combination thereof, as appropriate for the exposure radiation being used, or for other factors such as the use of an immersion liquid or the use of a vacuum. Any use of the term “projection lens” herein may be considered as synonymous with the more general term “projection system”.

As here depicted, the apparatus is of a transmissive type (e.g. employing a transmissive mask). Alternatively, the apparatus may be of a reflective type (e.g. employing a programmable minor array of a type as referred to above, or employing a reflective mask).

The lithographic apparatus may be of a type having two (dual stage) or more substrate tables or “substrate supports” (and/or two or more mask tables or “mask supports”). In such “multiple stage” machines the additional tables or supports may be used in parallel, or preparatory steps may be carried out on one or more tables or supports while one or more other tables or supports are being used for exposure.

The lithographic apparatus may also be of a type wherein at least a portion of the substrate may be covered by a liquid having a relatively high refractive index, e.g. water, so as to fill a space between the projection system and the substrate. An immersion liquid may also be applied to other spaces in the lithographic apparatus, for example, between the mask and the projection system Immersion techniques can be used to increase the numerical aperture of projection systems. The term “immersion” as used herein does not mean that a structure, such as a substrate, must be submerged in liquid, but rather only means that a liquid is located between the projection system and the substrate during exposure.

Referring to FIG. 1, the illuminator IL receives a radiation beam from a radiation source SO. The source and the lithographic apparatus may be separate entities, for example when the source is an excimer laser. In such cases, the source is not considered to form part of the lithographic apparatus and the radiation beam is passed from the source SO to the illuminator IL with the aid of a beam delivery system BD including, for example, suitable directing minors and/or a beam expander. In other cases the source may be an integral part of the lithographic apparatus, for example when the source is a mercury lamp. The source SO and the illuminator IL, together with the beam delivery system BD if required, may be referred to as a radiation system.

The illuminator IL may include an adjuster AD configured to adjust the angular intensity distribution of the radiation beam. Generally, at least the outer and/or inner radial extent (commonly referred to as a-outer and a-inner, respectively) of the intensity distribution in a pupil plane of the illuminator can be adjusted. In addition, the illuminator IL may include various other components, such as an integrator IN and a condenser CO. The illuminator may be used to condition the radiation beam, to have a desired uniformity and intensity distribution in its cross section.

The radiation beam B is incident on the patterning device (e.g., mask MA), which is held on the mask support structure (e.g., mask table MT), and is patterned by the patterning device. Having traversed the mask MA, the radiation beam B passes through the projection system PS, which focuses the beam onto a target portion C of the substrate W. With the aid of the second positioning device PW and position sensor IF (e.g. an interferometric device, linear encoder or capacitive sensor), the substrate table WT can be moved accurately, e.g. so as to position different target portions C in the path of the radiation beam B. Similarly, the first positioning device PM and another position sensor (which is not explicitly depicted in FIG. 1) can be used to accurately position the mask MA with respect to the path of the radiation beam B, e.g. after mechanical retrieval from a mask library, or during a scan. In general, movement of the mask table MT may be realized with the aid of a long-stroke module (coarse positioning) and a short-stroke module (fine positioning), which form part of the first positioning device PM. Similarly, movement of the substrate table WT or “substrate support” may be realized using a long-stroke module and a short-stroke module, which form part of the second positioner PW. In the case of a stepper (as opposed to a scanner) the mask table MT may be connected to a short-stroke actuator only, or may be fixed. Mask MA and substrate W may be aligned using mask alignment marks M1, M2 and substrate alignment marks P1, P2. Although the substrate alignment marks as illustrated occupy dedicated target portions, they may be located in spaces between target portions (these are known as scribe-lane alignment marks). Similarly, in situations in which more than one die is provided on the mask MA, the mask alignment marks may be located between the dies.

The depicted apparatus could be used in at least one of the following modes:
1. In step mode, the mask table MT or “mask support” and the substrate table WT or “substrate support” are kept essentially stationary, while an entire pattern imparted to the radiation beam is projected onto a target portion C at one time (i.e. a single static exposure). The substrate table WT or “substrate support” is then shifted in the X and/or Y direction so that a different target portion C can be exposed. In step mode, the maximum size of the exposure field limits the size of the target portion C imaged in a single static exposure.
2. In scan mode, the mask table MT or “mask support” and the substrate table WT or “substrate support” are scanned synchronously while a pattern imparted to the radiation beam is projected onto a target portion C (i.e. a single dynamic exposure). The velocity and direction of the substrate table WT or “substrate support” relative to the mask table MT or “mask support” may be determined by the (de-)magnification and image reversal characteristics of the projection system PS. In scan mode, the maximum size of the exposure field limits the width (in the non-scanning direction) of the target portion in a single dynamic exposure, whereas the length of the scanning motion determines the height (in the scanning direction) of the target portion.
3. In another mode, the mask table MT or “mask support” is kept essentially stationary holding a programmable patterning device, and the substrate table WT or “substrate support” is moved or scanned while a pattern imparted to the radiation beam is projected onto a target portion C. In this mode, generally a pulsed radiation source is employed and the programmable patterning device is updated as required after each movement of the substrate table WT or “substrate support” or in between successive radiation pulses during a scan. This mode of operation can be readily applied to maskless lithography that utilizes programmable patterning device, such as a programmable mirror array of a type as referred to above.

Combinations and/or variations on the above described modes of use or entirely different modes of use may also be employed.

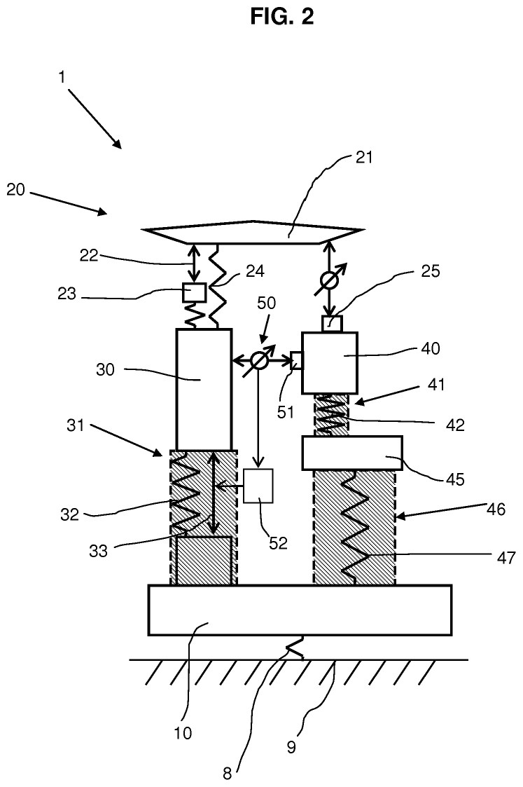

FIG. 2 shows a first embodiment of a lithographic apparatus 1 according to the invention.

The lithographic apparatus 1 comprises a base frame 10. The base frame 10 is adapted for mounting the lithographic apparatus 1 on a support surface 9. The support surface 9 can for example be a factory floor, a foundation or a pedestal. The base frame 10 is optionally arranged on the support surface by one or more supports, which is in FIG. 2 schematically indicated by spring 8.

The lithographic apparatus 1 further comprises a projection system 20. The projection system 20 comprises at least one optical element 21, which in this example is a mirror.

The projection system 20 further comprises a force frame 30. In the embodiment shown in FIG. 2, the optical element 21 is supported onto the force frame by a magnetic gravity compensator 24. An actuator 22 is provided to move the optical element 21, for example in order to control the position of the optical element 21 or to allow the optical element 21 to perform a scanning motion. A resiliently mounted reaction mass 23 is provided for the actuator 22. Optionally, the reaction mass 23 is provided with a vibration isolator. The optical element 21 is moveable relative to the force frame 30.

The projection system 20 further comprises a sensor frame 40. The sensor frame 40 is separate from the force frame 30. The force frame 30 can therewith move independently from the sensor frame 40. When the force frame 30 is moved or deformed, this movement or deformation is not directly transferred to the sensor frame 40. This arrangement provides a further disconnection between the force frame 30 and the sensor frame 40, making that vibrations, forces and deformations of the force frame 30 are not, or at least to a lesser extent, transferred to the sensor frame 40.

The projection system further comprises a sensor. The sensor comprises at least one sensor element 25, which is arranged on the sensor frame 40. The sensor is adapted to monitor the optical element 21.

Optionally, the sensor is adapted to generate measurement data relating to the position of the optical element 21 relative to the sensor frame 40. The sensor can for example comprise an interferometric device, an encoder-based device (comprising e.g. a linear encoder) or a capacitive sensor.

The sensor optionally comprises a sensor sender/receiver element and a sensor target element. If the sensor is an encoder based device, the sensor optionally comprises a grating, e.g. a one dimensional or two dimensional grating, which is for example arranged on the optical element 21 and an encoder head, which comprises a beam source and at least one receiver element which is adapted to receive the beam from the grating, which encoder head is for example arranged on the sensor frame 40. Alternatively, the grating may be arranged on the sensor frame 40 and the encoder head may be arranged on the optical element 21.

If the sensor is interferometer based, the sensor comprises a mirror element which is for example arranged on the optical element 21, a source for an optical beam and a receiver which is adapted to receive the beam from the mirror element. The source for the optical beam is arranged such that the optical beam strikes the mirror element on the optical element 21. Alternatively, the mirror element may for example be arranged on the sensor frame 40.

The lithographic apparatus 1 further comprises a force frame support 31, which is adapted to support the force frame 30 on the base frame 10.

In addition, the lithographic apparatus 1 comprises an intermediate frame 45, which is separate from the force frame 30. The force frame 30 can therewith move independently from the intermediate frame 45. When the force frame 30 is moved or deformed, this movement or deformation is not directly transferred to the intermediate frame 45. This arrangement provides a further disconnection between the force frame 30 and the sensor frame 40, making that vibrations, forces and deformations of the force frame 30 are not, or at least to a lesser extent, transferred to the sensor frame 40. In the embodiment of FIG. 2, the intermediate frame 45 is arranged below the sensor frame 40, but in an alternative embodiment, the intermediate frame 45 may be arranged above the sensor frame 40.

The sensor frame 40 is coupled to the intermediate frame 45 by a sensor frame coupler 41. The sensor frame coupler 41 may be for example be or comprise a sensor frame support with a vibration isolator, or a magnetic coupling device such as a magnetic gravity compensator.

The intermediate frame 45 is supported on the base frame 10 by an intermediate frame support 46, which is separate from the force fame support 31.

This arrangement makes that movement and deformation of the force frame 30, which are for example caused by movement of the optical element 21 relative to the force frame 30 (for example for the purpose of positioning the optical element 21 relative to the beam or to other optical elements of the projection system, or due to scanning movement that is imparted on the optical element 21), is not directly transferred to the sensor frame 40. This arrangement provides a further disconnection between the force frame 30 and the sensor frame 40, making that vibrations, forces and deformations of the force frame 30 are not, or at least to a lesser extent, transferred to the sensor frame 40. This increases the stability and position accuracy of the sensor frame 40, which for example allows to determine the position of the optical element 21 more accurately. A more accurate determination of the position of the optical element 21 allows to position the optical element 21 more accurately, which increases the projection accuracy and therewith reduces the overlay.

In addition, the vibration isolation from the force frame 30 relative to the base frame 10 and the vibration isolation of the sensor frame from the base frame 10 can both be optimised independently from each other. This allows specific optimisation of the vibration isolation of the force frame 30 and of the sensor frame 40 separately, taking into account the specific requirements and circumstances in each of these subsystems. For example, vibration isolation of the force frame 30 can be designed to accommodate a relatively large displacement of the optical element 21 (for example if a scanning motion of the optical element 21 is desired), while at same time the sensor frame 40 can be provided with a high level of vibration isolation at relatively low frequencies. By applying the current invention, there is no need to strike a compromise between those sometimes conflicting requirements.

Because the invention allows this kind of individual optimisation, the stability and positioning accuracy of the sensor frame 40 can be increased. Again, this allows to determine the position of the optical element 21 more accurately and a more accurate determination of the position of the optical element 21 allows to position the optical element 21 more accurately, which increases the projection accuracy and therewith reduces the overlay error.

In the embodiment of FIG. 2, the force frame support 31 comprises a vibration isolator 32. The sensor frame coupler 41 comprises a vibration isolator 42. The intermediate frame support 46 comprises a vibration isolator 47.

Optionally, each vibration isolator 32, 42, 47 comprises a pneumatic vibration isolator device or a plurality of pneumatic vibration isolator devices. The use of pneumatic vibration isolator devices allows to choose a specific isolation frequency (above which the vibrations will be effectively damped) from a large range of available products, each having their specific combinations of product specifications, because pneumatic vibration isolator devices are readily available in many shapes and sizes.

Optionally, both the force frame support 31 and the intermediate frame support 46 comprise a vibration isolator 32, 47 having an isolation frequency. The vibration isolator effectively dampens vibrations above the isolation frequency, so that the vibration isolation is effective for vibrations having a frequency above the isolation frequency. The isolation frequency of the vibration isolator 32 of the force frame support 31 is optionally higher than the isolation frequency of the vibration isolator 47 of the intermediate frame support 46. This allows an effective vibration isolation of the sensor frame 40, starting already at relatively low frequencies. The requirements for vibration isolation in the low frequency range of the force frame 30 are not so strict as the requirements for vibration isolation in the low frequency range of the sensor frame 40, so the force frame support 31 can be provided with a simpler and/or cheaper vibration isolator.

Optionally, both the sensor frame coupler 41 and the intermediate frame support 46 comprise a vibration isolator 42,47 having a isolation frequency. The isolation frequency of the vibration isolator 42 of the sensor frame coupler 41 is optionally higher than the isolation frequency of the vibration isolator 47 of the intermediate frame support 46. The vibration isolation of the sensor frame 40 is therewith a two-step arrangement, which allows to optimize the design of the vibration isolation. This arrangement of having two vibration isolators 42, 47 in series provides increased isolation for vibrations with a high frequency.

Optionally, the lithographic apparatus 1 in accordance with FIG. 2 further comprises a force frame control system 50. The force frame control system 50 comprises a force frame position sensor 51, a force frame actuator 33 and a force frame actuator control device 52.

The force frame position sensor 51 is adapted to generate measurement data relating to the position of the force frame 30 relative to the sensor frame 40. The force frame position sensor 51 can for example comprise an interferometric device, an encoder-based device (comprising e.g. a linear encoder) or a capacitive sensor. Optionally, the force frame position sensor 51 comprises a plurality of sensor elements.

The force frame position sensor 51 optionally comprises a sensor sender/receiver element and a sensor target element. Optionally, the force frame position sensor comprises a plurality of sensor sender/receiver elements and sensor target elements. If the force frame position sensor 51 is an encoder based device, the sensor optionally comprises a grating, e.g. a one dimensional or two dimensional grating, which is for example arranged on the force frame 30 and an encoder head, which comprises a beam source and at least one receiver element which is adapted to receive the beam from the grating, which encoder head is for example arranged on the sensor frame 40. Alternatively, the grating may be arranged on the sensor frame 40 and the encoder head may be arranged on the force frame 30.

If the sensor is interferometer based, the sensor comprises a mirror element which is for example arranged on the force frame 30, a source for an optical beam and a receiver which is adapted to receive the beam from the mirror element. The source for the optical beam is arranged such that the optical beam strikes the mirror element on the force frame 30. Alternatively, the mirror element may for example be arranged on the sensor frame 40.

The force frame actuator 33 is adapted to move the force frame 30 relative to the sensor frame 40. Optionally, the force frame actuator 33 is integrated into the force frame support 31, which makes that the force frame support 31 is turned into an active support. The addition of the actuator makes that the force frame support is adapted to move the force frame 30 relative to the sensor frame 40 (and relative to the base frame 10), which allows to actively control the position of the force frame 30 relative to the sensor frame 40. This allows an increased positioning accuracy of the optical element 21, and therewith an improvement of the projection accuracy and a reduction of the overlay. The force frame actuator 33 is for example an electromagnetic actuator such as a Lorentz actuator or a reluctance actuator.

The force frame actuator control device 52 of the force frame control system 50 is adapted to receive the measurement data from the force frame position sensor 51 and to control the force frame actuator 33 based on the received measurement data.

Optionally, in the embodiment of FIG. 2, the sensor frame coupler 41 and/or the intermediate frame support 46 are passive. In this variant, the sensor frame coupler 41 is not provided with an actuator, so that the sensor frame 40 is not actively moved relative to the intermediate frame 45. Likewise, the intermediate frame support 46 is not provided with an actuator, so that the intermediate frame 45 is not actively moved relative to the base frame 10. Alternatively, the sensor frame coupler 41 and/or the intermediate frame support 46 may comprise an actuator, in order to actively move the sensor frame 40 relative to the intermediate frame 45 and/or to actively move the intermediate frame 45 relative to the base frame 10.

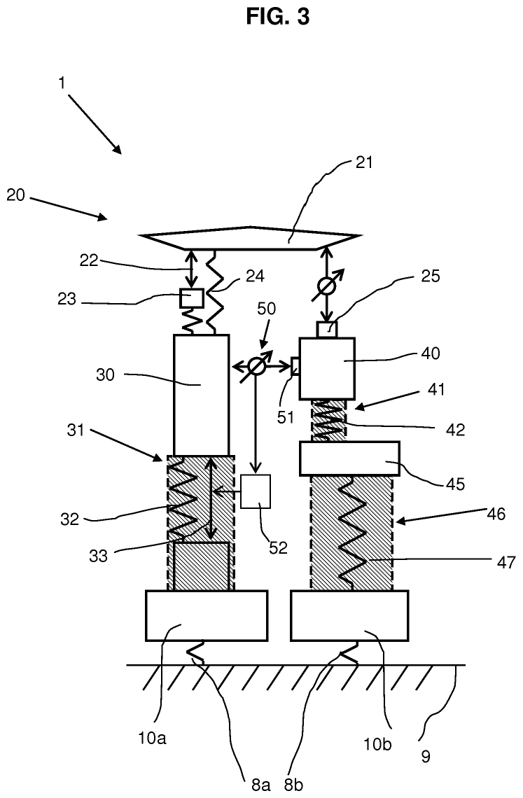

FIG. 3 shows a second embodiment of a lithographic apparatus 1 according to the invention, which is a variant of the embodiment of FIG. 2.

In the embodiment of FIG. 3, the base frame comprises a first base frame section 10a and a second base frame section 10b. The first and second base frame sections 10a, 10b are moveable relative to each other. Optionally, the first and second base frame sections 10a, 10b are separate from each other. Alternatively, the first and second base frame sections 10a, 10b may be connected to each other by a flexible connection, e.g. an elastic hinge. As a further alternative, the first and second base frame sections 10a, 10b may be connected to each other by a connector comprising a vibration isolator. As a further alternative, the first and second base frame sections 10a, 10b may be connected to each other by a deformable seal which is arranged to bridge a gap between the first base frame section 10a and the second base frame section 10b.

The base frame sections 10a, 10b are adapted for mounting the lithographic apparatus 1 on a support surface 9. The support surface 9 can for example be a factory floor, a foundation or a pedestal. The base frame sections 10a, 10b are optionally arranged on the support surface by one or more supports, which in FIG. 3 are schematically indicated by springs 8a, 8b.

In the embodiment according to FIG. 3, the force frame support 31 is connected to the first base frame section 10a and the intermediate frame support 46 is connected to the second base frame section 10b. This arrangement provides a further disconnection between the force frame 30 and the sensor frame 40, making that vibrations, forces and deformations of the force frame 30 are not, or at least to a lesser extent, transferred to the sensor frame 40.

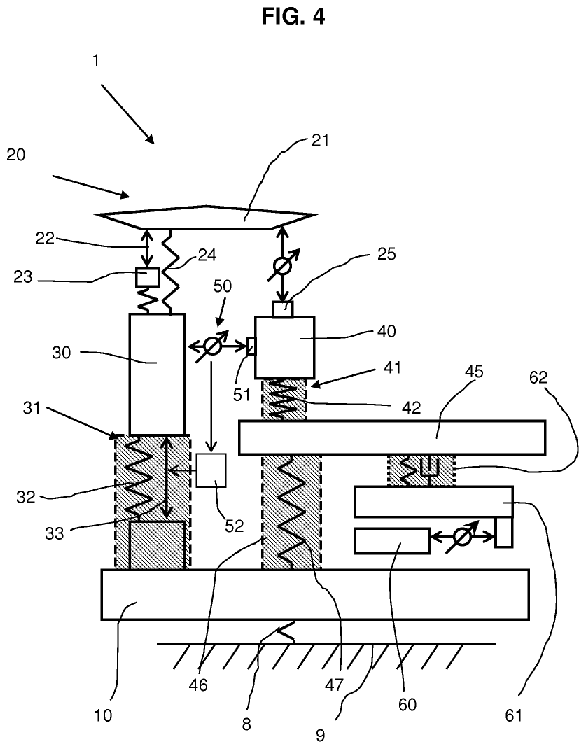

FIG. 4 shows a third embodiment of a lithographic apparatus 1 according to the invention, which is a variant of the embodiment of FIG. 2.

In the embodiment of FIG. 4, the lithographic apparatus further comprises a wafer stage 60 and a wafer stage measurement frame 61. In addition, a wafer stage measurement frame coupler 62 is provided which is adapted to couple the wafer stage measurement frame 61 to the intermediate frame 45. The wafer stage measurement frame 61 may be arranged above or below the intermediate frame 45. The wafer stage measurement frame coupler 62 may be for example be or comprise a sensor frame support with a vibration isolator, or a magnetic coupling device such as a magnetic gravity compensator.

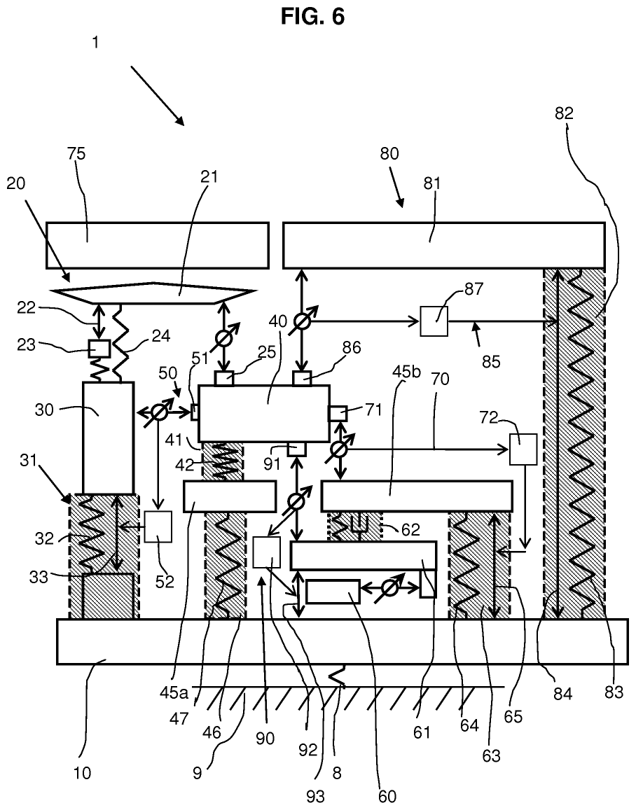

The wafer stage 60 is adapted to support and position a substrate. The position of the wafer stage 60 needs to be monitored accurately. To that end, at least one position sensor is provided, e.g. an interferometer based sensor, an encoder based sensor and/or a capacitive sensor. The sensor each comprises at least one sensor element, which is arranged on the wafer stage measurement frame 61. Optionally, the lithographic apparatus according to FIG. 4 further comprises a wafer stage measurement control system 90 of the types shown in FIG. 6.

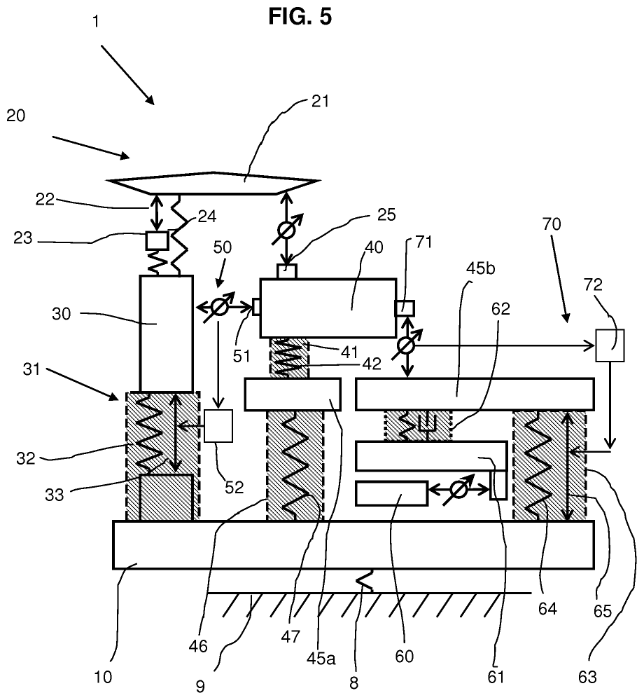

FIG. 5 shows a fourth embodiment of a lithographic apparatus 1 according to the invention, which is a variant of the embodiment of FIG. 4.

In the embodiment of FIG. 5, the intermediate frame comprises a first intermediate frame section 45a and a second intermediate frame section 45b. The first and second intermediate frame sections 45a, 45b are moveable relative to each other. Optionally, the first and second intermediate frame sections 45a, 45b are separate from each other. Alternatively, the first and second intermediate frame sections 45a, 45b may be connected to each other by a flexible connection, e.g. an elastic hinge. As a further alternative, the first and second intermediate frame sections 45a, 45b may be connected to each other by a connector comprising a vibration isolator. As a further alternative, the first and second intermediate frame sections 45a, 45b may be connected to each other by a deformable seal which is arranged to bridge a gap between the first intermediate frame section 45a and the second intermediate frame section 45b.

In the embodiment of FIG. 5, the sensor frame coupler 41 is connected to the first intermediate frame section 45a, and the wafer stage measurement frame coupler 62 is connected to the second intermediate frame section 45b. This arrangement provides a disconnection between the wafer stage measurement frame 61 and the sensor frame 40, making that vibrations, forces and deformations of the wafer stage measurement frame 61 are not, or at least to a lesser extent, transferred to the sensor frame 40. In addition, it allows freedom of design with respect to selecting the position of the first intermediate frame section 45a and the second intermediate frame section 45b within the lithographic apparatus.

Optionally, in the embodiment according to FIG. 5, the intermediate frame support 46 is connected to the first intermediate frame section 45a. The lithographic apparatus 1 further comprises a secondary intermediate frame support 63. The secondary intermediate frame support 63 is adapted to connect the second intermediate frame section 45b to the base frame 10.

Optionally, the secondary intermediate frame support 63 comprises a vibration isolator 64. Optionally, the vibration isolator 64 comprises a pneumatic vibration isolator device or a plurality of pneumatic vibration isolator devices.

Optionally, in this embodiment, the base frame 10 comprises a third base frame section, to which the secondary intermediate frame support 63 is connected. The base frame optionally further comprises a first base frame section and a second base frame section. The first, second and third base frame sections are moveable relative to each other. Optionally, the first, second and third base frame sections are separate from each other. Alternatively, at least two of the first, second and third base frame sections may be connected to each other by a flexible connection, e.g. an elastic hinge. As a further alternative, at least two of the first, second and third base frame sections may be connected to each other by a connector comprising a vibration isolator. As a further alternative, at least two of the first, second and third base frame sections may be connected to each other by a deformable seal which is arranged to bridge a gap between the respective base frame sections. Optionally, the force frame support 31 is connected to the first base frame section and the intermediate frame support 46 is connected to the second base frame section.

Alternatively, the base frame 10 comprises a primary base frame section and a secondary base frame section. The primary and secondary base frame sections are moveable relative to each other. Optionally, the primary and secondary base frame sections are separate from each other. Alternatively, the primary and secondary base frame sections may be connected to each other by a flexible connection, e.g. an elastic hinge. As a further alternative, the primary and secondary base frame sections may be connected to each other by a connector comprising a vibration isolator. As a further alternative, the primary and secondary base frame sections may be connected to each other by a deformable seal which is arranged to bridge a gap between the respective base frame sections. Optionally, the force frame support 31 is connected to the primary base frame section and the secondary intermediate frame support 63 is connected to the secondary base frame section. Optionally, both the force frame support 31 and the secondary intermediate frame support 63 are connected to the primary base frame section and the intermediate frame support 46 is connected to the secondary base frame section.

Optionally, in the embodiment of FIG. 5, the lithographic apparatus further comprises a second intermediate frame section control system 70. The second intermediate frame section control system 70 comprises second intermediate frame section position sensor 71, a second intermediate frame section actuator 65 and a second intermediate frame section actuator control device 72.

The secondary intermediate frame position sensor 71 is adapted to generate measurement data relating to the position of the secondary intermediate frame 45b relative to the sensor frame 40. The secondary intermediate frame position sensor 71 can for example comprise an interferometric device, an encoder-based device (comprising e.g. a linear encoder) or a capacitive sensor.

The secondary intermediate frame position sensor 71 optionally comprises a sensor sender/receiver element and a sensor target element. If the secondary intermediate frame position sensor 71 is an encoder based device, the sensor optionally comprises a grating, e.g. a one dimensional or two dimensional grating, which is for example arranged on the secondary intermediate frame 45b and an encoder head, which comprises a beam source and at least one receiver element which is adapted to receive the beam from the grating, which encoder head is for example arranged on the sensor frame 40. Alternatively, the grating may be arranged on the sensor frame 40 and the encoder head may be arranged on the secondary intermediate frame 45b.

If the sensor is interferometer based, the sensor comprises a mirror element which is for example arranged on the secondary intermediate frame 45b, a source for an optical beam and a receiver which is adapted to receive the beam from the mirror element. The source for the optical beam is arranged such that the optical beam strikes the mirror element on the secondary intermediate frame 45b. Alternatively, the mirror element may for example be arranged on the sensor frame 40.

The secondary intermediate frame actuator 65 is adapted to move the secondary intermediate frame 45b relative to the sensor frame 40. Optionally, the secondary intermediate frame actuator 65 is integrated into the secondary intermediate frame support 63, which makes that the secondary intermediate frame support 63 is turned into an active support. The addition of the actuator makes that the secondary intermediate frame support is adapted to move the secondary intermediate frame 45b relative to the sensor frame 40 (and relative to the base frame 10), which allows to actively control the position of the secondary intermediate frame 45b relative to the sensor frame 40. This allows an increased positioning accuracy of the optical element 21, and therewith an improvement of the projection accuracy and a reduction of the overlay. In addition, in some embodiments, the level of the requirements for the position measurement system of the wafer stage 60 can be reduced, e.g. with respect to the required range of measurement. The secondary intermediate frame actuator 65 is for example an electromagnetic actuator such as a Lorentz actuator or a reluctance actuator.

The secondary intermediate frame actuator control device 72 of the secondary intermediate frame control system 70 is adapted to receive the measurement data from the secondary intermediate frame position sensor 71 and to control the secondary intermediate frame actuator 65 based on the received measurement data.

Optionally, the lithographic apparatus according to FIG. 4 further comprises a wafer stage measurement control system 90 of the types shown in FIG. 6.

FIG. 6 shows a fifth embodiment of a lithographic apparatus 1 according to the invention, which is a variant of the embodiment of FIG. 5.

In the embodiment of FIG. 6, the lithographic apparatus further comprises an illumination system 80 configured to condition a radiation beam. The illumination system 80 comprises an illuminator frame 81 and an illuminator frame support 82. In addition, generally a patterning system 75 will be present as well. The patterning system 75 is arranged between the illumination system 80 and the projection system 20.

The illuminator frame 81 is separate from the sensor frame 40 of the projection system 20. The illuminator frame support 82 is adapted to connect the illuminator frame 81 to the base frame 10. The illuminator frame support 82 is separate from the force frame support and from the intermediate frame support 46. Optionally, the base frame 10 comprises a primary base frame section and a secondary base frame section, and the illuminator frame support 82 is arranged on the primary base frame section and the intermediate frame support 46 is arranged on the secondary base frame section.

In the embodiment of FIG. 6, the illuminator frame support 82 comprises a vibration isolator 83. Optionally, the vibration isolator 83 comprises a pneumatic vibration isolator device or a plurality of pneumatic vibration isolator devices.

Optionally, in the embodiment of FIG. 6, the lithographic apparatus further comprises an illuminator frame control system 85. The illuminator frame control system 85 comprises illuminator frame position sensor 86, a illuminator frame actuator 84 and a illuminator frame actuator control device 87.

The illuminator frame position sensor 86 is adapted to generate measurement data relating to the position of the illuminator frame 81 relative to the sensor frame 40. The illuminator frame position sensor 86 can for example comprise an interferometric device, an encoder-based device (comprising e.g. a linear encoder) or a capacitive sensor.

The illuminator frame position sensor 86 optionally comprises a sensor sender/receiver element and a sensor target element. If the illuminator frame position sensor 86 is an encoder based device, the sensor optionally comprises a grating, e.g. a one dimensional or two dimensional grating, which is for example arranged on the illuminator frame 81 and an encoder head, which comprises a beam source and at least one receiver element which is adapted to receive the beam from the grating, which encoder head is for example arranged on the sensor frame 40. Alternatively, the grating may be arranged on the sensor frame 40 and the encoder head may be arranged on the illuminator frame 81.

If the sensor is interferometer based, the sensor comprises a mirror element which is for example arranged on the illuminator frame 81, a source for an optical beam and a receiver which is adapted to receive the beam from the mirror element. The source for the optical beam is arranged such that the optical beam strikes the mirror element on the illuminator frame 81. Alternatively, the mirror element may for example be arranged on the sensor frame 40.

The illuminator frame actuator 84 is adapted to move the illuminator frame 81 relative to the sensor frame 40. Optionally, the illuminator frame actuator 84 is integrated into the illuminator frame support 82, which makes that the illuminator frame support 82 is turned into an active support. The addition of the actuator makes that the illuminator frame support is adapted to move the illuminator frame 81 relative to the sensor frame 40 (and relative to the base frame 10), which allows to actively control the position of the illuminator frame 81 relative to the sensor frame 40. The illuminator frame actuator 84 is for example an electromagnetic actuator such as a Lorentz actuator or a reluctance actuator.

The illuminator frame actuator control device 87 of the illuminator frame control system 85 is adapted to receive the measurement data from the illuminator frame position sensor 86 and to control the illuminator frame actuator 84 based on the received measurement data.

Optionally, in the embodiment of FIG. 6, the lithographic apparatus further comprises a wafer stage measurement frame control system 90. The wafer stage measurement frame control system 90 comprises wafer stage measurement frame position sensor 91, a wafer stage measurement frame actuator 93 and a wafer stage measurement frame actuator control device 92.

The wafer stage measurement frame position sensor 91 is adapted to generate measurement data relating to the position of the wafer stage measurement frame 61 relative to the sensor frame 40. The wafer stage measurement frame position sensor 91 can for example comprise an interferometric device, an encoder-based device (comprising e.g. a linear encoder) or a capacitive sensor.

The wafer stage measurement frame position sensor 91 optionally comprises a sensor sender/receiver element and a sensor target element. If the wafer stage measurement frame position sensor 91 is an encoder based device, the sensor optionally comprises a grating, e.g. a one dimensional or two dimensional grating, which is for example arranged on the wafer stage measurement frame 61 and an encoder head, which comprises a beam source and at least one receiver element which is adapted to receive the beam from the grating, which encoder head is for example arranged on the sensor frame 40. Alternatively, the grating may be arranged on the sensor frame 40 and the encoder head may be arranged on the wafer stage measurement frame 61.

If the sensor is interferometer based, the sensor comprises a mirror element which is for example arranged on the wafer stage measurement frame 61, a source for an optical beam and a receiver which is adapted to receive the beam from the mirror element. The source for the optical beam is arranged such that the optical beam strikes the mirror element on the wafer stage measurement frame 61. Alternatively, the mirror element may for example be arranged on the sensor frame 40.

The wafer stage measurement frame actuator 93 is adapted to move the wafer stage measurement frame 61 relative to the sensor frame 40. The wafer stage measurement frame actuator 93 is for example an electromagnetic actuator such as a Lorentz actuator or a reluctance actuator.

The wafer stage measurement frame actuator control device 92 of the wafer stage measurement frame control system 90 is adapted to receive the measurement data from the wafer stage measurement frame position sensor 91 and to control the wafer stage measurement frame actuator 93 based on the received measurement data.

Alternatively or in addition, the measurement signal generated by the wafer stage measurement frame position sensor 91 is used to calculate the position of the wafer stage 60 relative to the sensor frame 40. The measurement signal can be used to actively control the position of the wafer stage measurement frame 60, or a part of a wafer stage position measurement arrangement.

The wafer stage measurement control system 90 can also be applied in the embodiments of FIG. 4 and FIG. 5.

Although specific reference may be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, liquid-crystal displays (LCDs), thin film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track (a tool that typically applies a layer of resist to a substrate and develops the exposed resist), a metrology tool and/or an inspection tool. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

Although specific reference may have been made above to the use of embodiments of the invention in the context of optical lithography, it will be appreciated that the invention may be used in other applications, for example imprint lithography, and where the context allows, is not limited to optical lithography. In imprint lithography a topography in a patterning device defines the pattern created on a substrate. The topography of the patterning device may be pressed into a layer of resist supplied to the substrate whereupon the resist is cured by applying electromagnetic radiation, heat, pressure or a combination thereof. The patterning device is moved out of the resist leaving a pattern in it after the resist is cured.

The terms “radiation” and “beam” used herein encompass all types of electromagnetic radiation, including ultraviolet (UV) radiation (e.g. having a wavelength of or about 365, 248, 193, 157 or 126 nm) and extreme ultra-violet (EUV) radiation (e.g. having a wavelength in the range of 5-20 nm), as well as particle beams, such as ion beams or electron beams.

The term “lens”, where the context allows, may refer to any one or combination of various types of optical components, including refractive, reflective, magnetic, electromagnetic and electrostatic optical components.

While specific embodiments of the invention have been described above, it will be appreciated that the invention may be practiced otherwise than as described. For example, the invention may take the form of a computer program containing one or more sequences of machine-readable instructions describing a method as disclosed above, or a data storage medium (e.g. semiconductor memory, magnetic or optical disk) having such a computer program stored therein.

The descriptions above are intended to be illustrative, not limiting. Thus, it will be apparent to one skilled in the art that modifications may be made to the invention as described without departing from the scope of the claims set out below.

1.-21. (canceled)

22. A lithographic apparatus, comprising:
a base frame configured to mount the lithographic apparatus on a support surface; and
a projection system comprising
a force frame,
an optical element configured to be moveable relative to the force frame,
a sensor frame disposed separate from the force frame,
at least one sensor configured to monitor the optical element, wherein the at least one sensor comprises at least one sensor element that is mounted to the sensor frame,
a force frame support configured to support the force frame on the base frame,
an intermediate frame disposed separate from the force frame,
a sensor frame coupler configured to couple the sensor frame to the intermediate frame, and
an intermediate frame support, disposed separate from the force fame support, and configured to support the intermediate frame on the base frame.

23. The lithographic apparatus of claim 22, wherein at least one of the force frame support, the sensor frame coupler, and the intermediate frame support comprises a vibration isolator.

24. The lithographic apparatus of claim 22, wherein the lithographic apparatus further comprises a force frame control system comprising:
a force frame position sensor configured to generate measurement data relating to the position of the force frame relative to the sensor frame;
a force frame actuator configured to move the force frame relative to the sensor frame;
a force frame actuator control device configured to receive the measurement data from the force frame position sensor and to control the force frame actuator based on the received measurement data.

25. The lithographic apparatus of claim 24, wherein the force frame actuator forms part of the force frame support.

26. The lithographic apparatus of claim 22, wherein the sensor frame coupler is passive.

27. The lithographic apparatus of claim 22, wherein the base frame comprises a first base frame section and a second base frame section, wherein the first and the second base frame sections are moveable relative to each other, and
wherein the force frame support is connected to the first base frame section, and
wherein the intermediate frame support is connected to the second base frame section.

28. The lithographic apparatus of claim 22,
wherein both the force frame support and the intermediate frame support comprise a vibration isolator having an isolation frequency, and
wherein the isolation frequency of the vibration isolator of the force frame support is higher than the isolation frequency of the vibration isolator of the intermediate frame support.

29. The lithographic apparatus of claim 22,
wherein both the sensor frame coupler and the intermediate frame support comprise a vibration isolator having a isolation frequency, and
wherein the isolation frequency of the vibration isolator of the sensor frame coupler is higher than the isolation frequency of the vibration isolator of the intermediate frame support.

30. The lithographic apparatus of claim 22, wherein the lithographic apparatus further comprises a wafer stage measurement frame and a wafer stage measurement frame coupler configured to couple the wafer stage measurement frame to the intermediate frame.

31. The lithographic apparatus of claim 30,
wherein the intermediate frame comprises a first intermediate frame section and a second intermediate frame section, the first and the second intermediate frame sections configured to be moveable relative to each other, and
wherein the sensor frame coupler is connected to the first intermediate frame section, and
wherein the wafer stage measurement frame coupler is connected to the second intermediate frame section.

32. The lithographic apparatus of claim 31,
wherein the intermediate frame support is connected to the first intermediate frame section, and
wherein the lithographic apparatus further comprises a secondary intermediate frame support configured to connect the second intermediate frame section to the base frame.

33. The lithographic apparatus of the claim 31, wherein the lithographic apparatus further comprises a second intermediate frame section control system comprising:
a second intermediate frame section position sensor configured to generate measurement data relating to the position of the second intermediate frame section relative to the sensor frame;
a second intermediate frame section actuator configured to move the second intermediate frame section relative to the sensor frame; and
a second intermediate frame section actuator control device configured to receive the measurement data from the second intermediate frame section position sensor and to control the second intermediate frame section actuator based on the received measurement data.

34. The lithographic apparatus of the claim 30, wherein the lithographic apparatus further comprises a wafer stage measurement frame control system comprising:
a wafer stage measurement frame position sensor configured to generate measurement data relating to the position of the wafer stage measurement frame relative to the sensor frame.

35. The lithographic apparatus of claim 34, wherein the wafer stage measurement frame control system further comprises:
a wafer stage measurement frame actuator configured to move the wafer stage measurement frame relative to the sensor frame; and
a wafer stage measurement frame actuator control device configured to receive the measurement data from the wafer stage measurement frame position sensor and to control the wafer stage measurement frame actuator based on the received measurement data.

36. The lithographic apparatus of claim 22, wherein the lithographic apparatus further comprises an illumination system configured to condition a radiation beam, the illumination system comprising:
an illuminator frame disposed separate from the sensor frame of the projection system; and
an illuminator frame support configured to connect the illuminator frame to the base frame, and which is disposed separate from the force frame support and from the intermediate frame support.

37. The lithographic apparatus of claim 36, wherein the lithographic apparatus further comprises a illuminator frame control system comprising:
an illuminator frame position sensor configured to generate measurement data relating to the position of the illuminator frame relative to the sensor frame;
an illuminator frame actuator configured to move the illuminator frame relative to the sensor frame; and
an illuminator frame actuator control device configured to receive the measurement data from the illuminator frame position sensor and to control the illuminator frame actuator based on the received measurement data.

38. A lithographic apparatus, comprising:
an illumination system configured to condition a radiation beam;
a support constructed to support a patterning device, the patterning device configured to impart the radiation beam with a pattern in its cross-section to form a patterned radiation beam;
a base frame configured to mount the lithographic apparatus on a support surface;
a substrate table configured to hold a substrate; and
a projection system configured to project the patterned radiation beam onto a target portion of the substrate, which projection system comprises:
a force frame,
an optical element configured to move relative to the force frame,
a sensor frame disposed separate from the force frame,
at least one sensor configured to monitor the optical element, wherein the at least one sensor is mounted to the sensor frame,
a force frame support configured to connect the force frame and the base frame to each other,
an intermediate frame disposed separate from the force frame,
a sensor frame coupler configured to connect the sensor frame and the intermediate frame to each other, and
an intermediate frame support disposed separate from the force fame support and configured to connect the intermediate frame and the base frame to each other.

39. A lithographic projection apparatus arranged to project a pattern from a patterning device onto a substrate, comprising:
a base frame configured to mount the lithographic apparatus on a support surface,
a projection system comprising:
a force frame,
an optical element configured to move relative to the force frame,
a sensor frame disposed separate from the force frame,
at least one sensor configured to monitor the optical element, wherein the at least one sensor is mounted to the sensor frame,
a force frame support configured to connect the force frame and the base frame to each other,
an intermediate frame disposed separate from the force frame,
a sensor frame coupler configured to connect the sensor frame and the intermediate frame to each other, and
an intermediate frame support disposed separate from the force fame support and configured to connect the intermediate frame and the base frame to each other.
